(19) United States
(12) Patent Application Publication
(10) Pub. No.: US 2005/0194681 A1
(43) Pub. Date: Sep. 8, 2005

(54) Conductive pad with high abrasion

(76) Inventors: Yongqi Hu, San Jose, CA (US); Stan D. Tsai, Fremont, CA (US); Martin S. Wohlert, San Jose, CA (US); Feng Q. Liu, San Jose, CA (US); Liang-Yuh Chen, Foster City, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 11/066,599

(22) Filed: Feb. 25, 2005

Related U.S. Application Data
(63) Continuation-in-part of application No. 10/980,888, filed on Nov. 3, 2004.
(63) Continuation-in-part of application No. 10/744,904, filed on Dec. 23, 2003.
Application No. 10/744,904 is a continuation-in-part of application No. 10/642,128, filed on Aug. 15, 2003.
Application No. 10/642,128 is a continuation-in-part of application No. 10/608,513, filed on Jun. 26, 2003.
Application No. 10/608,513 is a continuation-in-part of application No. 10/140,010, filed on May 7, 2002.
(63) Continuation-in-part of application No. 10/455,941, filed on Jun. 6, 2003.
Application No. 10/455,941 is a continuation-in-part of application No. 10/455,895, filed on Jun. 6, 2003.
(60) Provisional application No. 60/516,680, filed on Nov. 3, 2003.

(51) Int. Cl. H01L 23/48

(52) U.S. Cl. 257/737

(57) ABSTRACT

A method and apparatus for a planarizing or polishing article for Electrochemical Mechanical Planarization (ECMP) is disclosed. The polishing article is a pad assembly having a plurality of conductive domains and a plurality of abrasive domains on a processing surface. The abrasive domains and the conductive domains comprise a plurality of contact elements that are adapted to bias a semiconductor substrate while also providing abrasive qualities to enhance removal of material deposited on the substrate.

### CROSS-REFERENCE TO RELATED APPLICATIONS

This application is a continuation-in-part of co-pending U.S. patent application Ser. No. 10/980,888 (Attorney Docket No. 4100P12), filed Nov. 3, 2004, which claims benefit of U.S. Provisional Patent Application Ser. No. 60/516,680 (Attorney Docket No. 4100L02), filed on Nov. 3, 2003. This application is also a continuation-in-part of co-pending U.S. patent application Ser. No. 10/744,904 (Attorney Docket No. 4100P10), filed Dec. 23, 2003. The Ser. No. 10/744,904 application is a continuation-in-part of co-pending U.S. patent application Ser. No. 10/642,128 (Attorney Docket No. 4100P8), filed Aug. 15, 2003. The Ser. No. 10/642,128 application is a continuation-in-part of co-pending U.S. patent application Ser. No. 10/608,513 (Attorney Docket No. 4100P7), filed Jun. 26, 2003, which is a continuation-in-part of co-pending U.S. patent application Ser. No. 10/140,010 (Attorney Docket No. 7047), filed May 7, 2002. This application is additionally a continuation in part of U.S. patent application Ser. No. 10/455,941 (Attorney Docket No. 4100P4), filed Jun. 6, 2003; and a continuation-in-part of U.S. patent application Ser. No. 10/455,895 (Attorney Docket No. 4100P5), filed Jun. 6, 2003. All of the prior applications are incorporated herein by reference in their entireties.

### BACKGROUND OF THE INVENTION

1. Field of the Invention

Embodiments of the present invention generally relate to a pad assembly for use in an electrochemical mechanical processing system.

2. Description of the Related Art

Electrochemical Mechanical Processing (ECMP) is a technique used to deposit or remove conductive materials from a substrate surface. For example, in an ECMP polishing process, conductive materials are removed from the surface of a substrate by electrochemical dissolution while concurrently polishing the substrate with reduced mechanical abrasion as compared to conventional Chemical Mechanical Polishing (CMP) processes, which typically rely on abrasive qualities of the pad material, or an abrasive slurry, for removal. While these processes may be used for the same purpose, the ECMP process is sometimes preferred because the removal rate is more easily controlled by varying specific parameters, such as electrical current.

Electrochemical dissolution is typically performed by applying an electrical bias between a cathode and the feature side i.e., deposit receiving surface of a substrate. The feature side of the substrate may have a conductive material that has been deposited by a deposition method such as, chemical vapor deposition (CVD), plasma enhanced chemical vapor deposition (PECVD), atomic layer deposition (ALD), or any method known in the art. The bias may be applied to the substrate by a conductive contact element disposed on or through a polishing material upon which the substrate is processed, and the conductive materials may be removed from the feature side of the substrate into a surrounding electrolyte.

The energization, e.g., biasing, of the conductive material has been accomplished in at least two different ways. One is by the use of conductive elements, such as pins at least partially contained in the pad that are adapted to contact the conductive material on a feature side of the substrate during processing. The conductive elements are movably mounted in an upper portion of a pad surface and are adapted to succumb to any downward pressure exerted by the substrate, while exerting a counter force sufficient to maintain mechanical contact with the substrate. Another is the use of a polishing pad with a surface that is fully conductive, adapted to contact the feature side of the substrate by a downward force exerted on the substrate. Another mechanical component of the polishing process, typically used in combination with the downward force, is added by providing relative motion between the substrate and the polishing pad that enhances the removal of the conductive material from the substrate. ECMP systems may alternatively be adapted for deposition of conductive material on the substrate by reversing the polarity of the bias.

Although conductive pins as conductive contact elements for biasing the conductive layer of a feature side of a substrate have demonstrated good results, short service life encourages searching for an alternative contact element. The pins have been known to create scratches in the substrate and to degrade over time, thus lowering throughput and causing possible substrate damage. A pad with a fully conductive surface may not cause mechanical scratches, may create shallow line structures in the feature side of the substrate. These shallow line structures are believed to be caused by non-uniform electrical contact with the substrate, either alone, or in combination with insufficient friction for abrasion. The lack of friction in fully conductive pads has been linked to the material properties of the elements needed for conductivity in the surface. These properties typically include conductive metals that will not react with process chemistry and are soft enough to inhibit scratching on the substrate surface. The resulting pad surface, containing elements exhibiting these properties, is conductive, but exhibits abrasive qualities that may be improved.

Therefore, there is a need in the art for an improved pad for electrochemical mechanical polishing that combines materials that exhibit an improved abrasive quality, while also providing a conductive surface capable of sustaining and transmitting an electrical bias.

### SUMMARY OF THE INVENTION

The present invention generally relates to a pad assembly for processing a substrate comprising a body with an upper conductive layer having an upper portion and a lower surface, wherein the upper portion has a processing surface. The body also has a first interpose layer having a lower surface and an upper surface adhered to the lower portion of the upper conductive layer, a sub pad having a lower surface and an upper surface adhered to the lower surface of the first interpose layer, a second interpose layer having a lower surface and an upper surface adhered to the lower surface of the sub pad, and an opposing second conductive layer having a lower surface and an upper surface adhered to the lower surface of the second interpose layer.

A method of manufacturing a pad assembly is also disclosed wherein a conductive composite material is compression molded with a plastic patterning mask screen and removed to form an embossed conductive surface. The grooves or channels formed in the embossed conductive surface are then filled with a plastic material to form an abrasive portion on the conductive pad, thereby creating a processing surface that is substantially planar. Another manufacturing method is disclosed wherein a plastic patterning mask screen is compressed onto a conductive composite material and left in the composite to form an abrasive portion of a conductive pad with a processing surface that is substantially planar. Still another method is disclosed where a pad with a substantially planar profile made by the methods described above is then compression molded or embossed down to a conductive carrier a second time to form grooves or channels in the processing surface. The portions remaining above the conductive carrier form posts that range in shape from ovals, substantial rectangles, or substantial hexagons, and the posts are made of a material that is partially conductive and partially abrasive.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side view, partially in cross-section, of one embodiment of an electrochemical mechanical processing station;

FIG. 2 is a partial sectional view of one embodiment of a pad assembly and platen of the processing station of FIG. 1;

FIG. 3 is a plan view of one embodiment of an electrode of a pad assembly of the processing station of FIG. 1;

FIG. 4 is an isometric view of one embodiment of a pad assembly.

FIG. 5 is an isometric view of another embodiment of a pad assembly;

FIG. 6 is an isometric view of another embodiment of a processing surface;

FIG. 7 is an isometric view of another embodiment of a processing surface.

### DETAILED DESCRIPTION

Although the embodiments of the invention disclosed herein focus primarily on polishing a substrate, it is contemplated that the teachings disclosed herein may be utilized to electroplate a substrate by reversing the polarity of the bias. Where applicable, common reference numerals are used to depict similar elements in the Figures. The terms contact element, or contact elements, are broadly defined as a part of a pad assembly adapted to contact the feature surface of a substrate and may possess conductive properties that sustain and transmit an electrical bias. The contact elements may be wholly made of a conductive material, wholly made of a non-conductive material, or a combination of a non-conductive material and a conductive material. The embodiments of contact elements of the pad assemblies depicted in the Figures may not be drawn to scale for clarity reasons.

The contact element described herein may be formed from conductive materials that may comprise a conductive polishing material or may comprise a conductive element disposed in a dielectric or conductive polishing material. In one embodiment, a conductive polishing material may include conductive fibers, conductive fillers, or combinations thereof. The conductive fibers, conductive fillers, or combinations thereof may be dispersed in a binder comprising polymeric material.

Examples of conductive polishing materials, including conductive fibers, are more fully described in co-pending U.S. patent application Ser. No. 10/033,732, filed on Dec. 27, 2001, entitled “Conductive Polishing Article for Electrochemical Mechanical Polishing”, and in U.S. patent application Ser. No. 10/980,888 (Attorney Docket No. 4100P12) entitled “Composite Pad Assembly for Electrochemical Mechanical Processing (ECMP), previously incorporated by reference in its entirety. The invention also contemplates the use of organic or inorganic materials that may be used as fibers described herein.

The conductive fiber material, the conductive filler material, or combinations thereof, may be dispersed in a binder material or form a composite conductive polishing material. One form of binder material is a conventional polishing material. Conventional polishing materials are generally dielectric materials such as dielectric polymeric materials. Examples of dielectric polymeric polishing materials include polyurethane and polyurethane mixed with fillers, polycarbonate, polyphenylene sulfide (PPS), Teflon™ polymers, polystyrene, ethylene-propylene-diene-methylene (EPDM), or combinations thereof, and other polishing materials used in polishing substrate surfaces. The conventional polishing material may also include felt fibers impregnated in urethane or be in a foamed state. The invention contemplates that any conventional polishing material may be used as a binder material, also known as a matrix, with the conductive fibers and fillers described herein.

Additives may be added to the binder material to assist the dispersion of conductive fibers, conductive fillers or combinations thereof, in the polymer materials. Additives may be used to improve the mechanical, thermal, and electrical properties of the polishing material formed from the fibers and/or fillers and the binder material. Additives include cross-linkers for improving polymer cross-linking and dispersants for dispersing conductive fibers or conductive fillers more uniformly in the binder material. Examples of cross-linkers include amino compounds, silane crosslinkers, polyisocyanate compounds, and combinations thereof. Examples of dispersants include N-substituted long-chain alkenyl succinimides, amine salts of high-molecular-weight organic acids, co-polymers of methacrylic or acrylic acid derivatives containing polar groups such as amines, amides, imines, imides, hydroxyl, ether, Ethylene-propylene copolymers containing polar groups such as amines, amides, imines, imides, hydroxyl, ether. In addition sulfur containing compounds, such as thioglycolic acid and related esters have been observed as effective dispersers for gold coated fibers and fillers in binder materials. The invention contemplates that the amount and types of additives will vary for the fiber or filler material as well as the binder material used, and the above examples are illustrative and should not be construed or interpreted as limiting the scope of the invention.

Alternatively, the conductive fibers and/or fillers may be combined with a bonding agent to form a composite conductive polishing material. Examples of suitable bonding agents include epoxies, silicones, urethanes, polyimides, a polyamide, a fluoropolymer, fluorinated derivatives thereof, or combinations thereof. Additional conductive material, such as conductive polymers, additional conductive fillers, or combinations thereof, may be used with the bonding agent for achieving desired electrical conductivity or other polishing article properties. The conductive fibers and/or fillers may include between about 2 wt. % and about 85 wt. %, such as between about 5 wt. % and about 60 wt. %, of the composite conductive polishing material.

The conductive fiber and/or filler material may be used to form conductive polishing materials or articles having bulk or surface resistivity of about 50 Ω-cm or less, such as a resistivity of about 3 Ω-cm or less. In one aspect of the polishing article, the polishing article or polishing surface of the polishing article has a resistivity of about 1 Ω-cm or less. Generally, the conductive polishing material or the composite of the conductive polishing material and conventional polishing material are provided to produce a conductive polishing article having a bulk resistivity or a bulk surface resistivity of about 50 Ω-cm or less. An example of a composite of the conductive polishing material and conventional polishing material includes gold or carbon coated fibers which exhibit resistivities of 1 Ω-cm or less, disposed in a conventional polishing material of polyurethane in sufficient amounts to provide a polishing article having a bulk resistivity of about 10 Ω-cm or less.

The contact elements formed from the conductive fibers and/or fillers described herein generally have mechanical properties that do not degrade under sustained electric fields and are resistant to degradation in acidic or basic electrolytes. The conductive material and any binder material used are combined to have equivalent mechanical properties, if applicable, of conventional polishing materials used in a conventional polishing article. For example, the conductive polishing material, either alone or in combination with a binder material, has a hardness of about 100 or less on the Shore D Hardness scale for polymeric materials as described by the American Society for Testing and Materials (ASTM), headquartered in Philadelphia, Pa. In one aspect, the conductive material has a hardness of about 80 or less on the Shore D Hardness scale for polymeric materials. The conductive polishing portion generally includes a surface roughness of about 500 microns or less. The properties of the polishing pad are generally designed to reduce or minimize scratching of the substrate surfaces during mechanical polishing and when applying a bias to the substrate surface.

Examples of conductive materials and structures suitable for use as contact elements are described in U.S. patent application Ser. No. 10/455,941, filed Jun. 6, 2003 by Y. Hu et al., entitled “Conductive Polishing Article for Electrochemical Mechanical Polishing”, and U.S. patent application Ser. No. 10/455,895, filed Jun. 6, 2003 by Y. Hu et al., with the same title, both previously incorporated by reference in their entireties. In one embodiment, the conductive layer consists of tin particles disposed in a polymer matrix. In another embodiment, the conductive layer consists of nickel and/or copper particles disposed in a polymer matrix. The mixture of particles in the polymer matrix may be disposed over a dielectric fabric coated with metal, such as copper, tin, or gold, and the like.

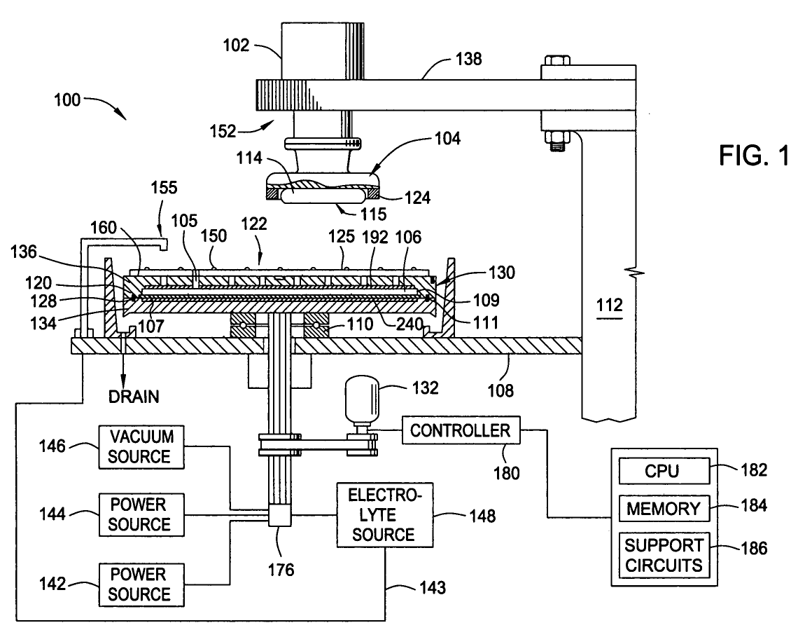

FIG. 1 depicts a sectional view of a processing station 100 having one embodiment of a pad assembly, such as a pad body 122, disposed on the processing station 100. The pad assembly 122, which includes at least one contact element 150, a processing surface 125, and an electrode 192, is seen on a platen assembly 130. The platen assembly 130 includes an upper plate 136 and a lower plate 134. The upper plate 136 may be fabricated from a rigid material, such as a metal or rigid plastic, and in one embodiment, is fabricated from or coated with a dielectric material, such as chlorinated polyvinyl chloride (CPVC). The upper plate 136 may have a circular, rectangular or other geometric form with a planar top surface 160. The top surface 160 of the upper plate 136 supports the pad assembly 122 thereon. The pad body 122 may be held to the upper plate 136 of the platen assembly 130 by a magnetic element 240, static attraction, vacuum, adhesives, or the like.

The lower plate 134 is generally fabricated from a rigid material, such as aluminum, and may be coupled to the upper plate 136 by any conventional means, such as a fastener 111. Generally, a plurality of locating pins 128 are disposed between the upper and lower plates 136, 134 to ensure alignment therebetween. An optional plenum 106 is defined in the platen assembly 130 and may be partially formed in at least one of the upper or lower plates 136, 134. In the embodiment depicted in FIG. 1, the optional plenum 106 is defined in a recess 109 partially formed in the lower surface of the upper plate 136. At least one hole 105 is formed in the upper plate 136 to allow electrolyte, provided to the plenum 106 from an electrolyte source 148, to flow through the platen assembly 130 and the electrode 192 into contact with the substrate 114 during processing. Alternatively or in combination, an electrolyte may be provided to the platen assembly 130 and the processing surface 125 of the pad body 122 by a nozzle 155. The nozzle 155 is connected to the electrolyte source 148 by appropriate plumbing and controls, such as conduit 143. The plenum 106 is partially bounded by a cover 107 coupled to the upper plate 136 and enclosing the recess 109. It is contemplated that platen assemblies without a plenum and having other configurations may be utilized.

The processing station 100 also includes a carrier head assembly 152 positioned over the platen assembly 130 by an arm 138 coupled to a column 112. The carrier head assembly 152 generally includes a drive system 102 coupled to a carrier head 104. The drive system 102 generally provides at least rotational motion to the carrier head 104. The carrier head 104, which includes a retaining ring to hold a substrate 114, additionally may be actuated toward the pad body 122 such that the feature side, i.e., the deposit receiving surface of the substrate 114, may be disposed against the processing surface 125 of the pad body 122 during processing. In one embodiment, the carrier head 104 may be a TITAN HEAD™ or TITAN PROFILERT™ wafer carrier manufactured by Applied Materials, Inc., of Santa Clara, Calif. It is contemplated that other carrier heads may be utilized.

The platen assembly 130 is rotationally disposed on a base 108. A bearing 110 is disposed between the platen assembly 130 and the base 108 to facilitate rotation of the platen assembly 130 relative to the base 108. A motor 132 is coupled to the platen assembly 130 to provide rotational motion. Relative motion is provided by the platen assembly 130 and the substrate 114 coupled to the carrier head 104 during processing. The relative motion may be rotational, linear, or some combination thereof and may be provided by at least one of the carrier head assembly 152 and the platen assembly 130.

The contact element 150 on the pad body 122 depicted in FIG. 1 is adapted to electrically couple the feature side 115 of the substrate 114 to a power source 144. The contact element 150 may be coupled to the platen assembly 130, part of the pad body 122, or a separate element, and is generally positioned to maintain contact with the substrate 114 during processing. The pad body 122 may include an electrode 192 coupled to a different terminal of the power source 144 such that an electrical potential may be established between the substrate 114 and the electrode 192 of the pad body 122. Electrolyte, which is introduced from the electrolyte source 148 and is disposed on the pad body 122, completes an electrical circuit between the substrate 114 and the electrode 192 as further discussed below, which assists in the removal of material from the feature surface 115 of the substrate 114.

The pad body 122 may be configured without an electrode 192, in which case the electrode may be disposed on or within the platen assembly 130. It is contemplated that multiple contact elements 150 and/or electrodes 192 may be used. The contact elements 150 and/or electrodes 192 may be independently biased.

To facilitate control of the processing station 100 as described above, a controller 180 is coupled to the processing station 100. The controller 180 is utilized to control power supplies, motors, drives, fluid supplies, valves, actuators, and other processing components of the processing station 100. The controller 180 comprises a central processing unit (CPU) 182, support circuits 186 and memory 184. The CPU 182 may be one of any form of computer processor that can be used in an industrial setting for controlling various chambers and sub-processors. The memory 184 is coupled to the CPU 182. The memory 184, or computer-readable medium, may be one or more of readily available memory such as random access memory (RAM), read only memory (ROM), floppy disk, hard disk, or any other form of digital storage, local or remote. The support circuits 186 are coupled to the CPU 182 for supporting the processor in a conventional manner. These circuits include cache, power supplies, clock circuits, input/output circuitry, subsystems, and the like.

The controller 180 may receive a metric indicative of processing performance for closed-loop process control of the processing station 100. For example, material removal in a polishing operation may be monitored by measuring and/or calculating the thickness of conductive material remaining on the substrate 114. The thickness of the material remaining on the substrate 114 may be measured and/or determined by, for example, optical measurement, interferometric end point, process voltage, process current, charge removed from the conductive material on the substrate, effluent component analysis, and other known means for detecting process attributes.

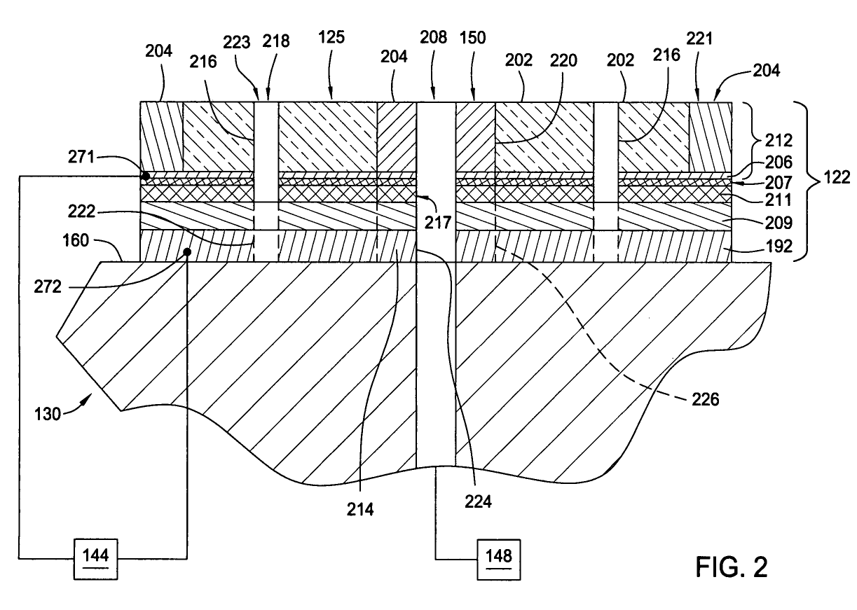

FIG. 2 depicts a partial sectional view of one embodiment of the pad body 122 disposed on a platen assembly. In this embodiment the pad body 122 includes at least a first conductive layer, such as upper portion 212, a first interpose layer, such as an upper interpose layer 207, a sub-pad 211, a second interpose layer, such as a lower interpose layer 209, and a second conductive layer, such as an electrode 192. The upper portion 212 of the pad body 122 comprises a processing surface 125 disposed on a conductive carrier 206. The processing surface 125 comprises a plurality of contact elements 150, which comprise a plurality of conductive surfaces, such as conductive domains 204 and a plurality of non-conductive surfaces, such as abrasive domains 202. An electrode 192 is disposed on the substantially planar upper surface 160 of the platen assembly 130 and may be held static by the methods mentioned above. The electrode 192, sub-pad 211, upper and lower interpose layers 207, 209, and upper portion 212 of the pad body 122, may be combined into a unitary assembly by the use of binders, such as a pressure and/or temperature sensitive adhesives, bonding, compression molding, or the like.

Also shown is a first permeable passage 218, which may extend through the pad body 122 at least to the electrode 192 and allows an electrolyte to establish a conductive path between the substrate 114 (shown in FIG. 1) and the electrode 192. The first permeable passage 218 may be a permeable portion of the pad assembly 122, holes formed in the pad body 122, or a combination both. The sub-pad 211 may also be formed of a permeable material, or may include holes which align with the permeable passages 218 formed in the upper portion 212. In the embodiment depicted in FIG. 2, the first permeable passage 218 may be a plurality of holes 216 (only two shown for clarity) formed in and through the sub-pad 211, interpose layers 207, 209 and upper portion 212 to allow electrolyte to flow therethrough and come into contact with the electrode 192 during processing. Optionally, an extension 222 of the permeable passage 218 (shown in phantom) may be formed in and at least partially through the electrode 192. The extension 222 may extend completely through the electrode 192, which will increase the surface area of the electrode 192 in contact with the electrolyte. The electrolyte, from the source 148, is used to improve the removal rate and may facilitate cooling of the processing surface 125, which may have increased temperature due to friction and electrical current flow, thereby enhancing process repeatability and extending service life of the pad body 122.

Optionally, a second permeable passage 208, similar to the hole 105 of FIG. 1, may also be used to allow electrolyte to establish a conductive path for the pad body 122 by allowing electrolyte delivery from an optional plenum 106 in the platen assembly 130. Optionally, an insulator 217 may be provided on at least a portion of an inner wall 224 of the second permeable passage 208 to prevent current from flowing directly between the processing surface 125 and the electrode 192 through the second permeable passage 208. When the electrolyte is delivered from the fluid delivery tube 255 (shown in FIG. 1) disposed above the pad assembly 122, the permeable passage 208 may not be used.

In the embodiment depicted in FIG. 2, the second permeable passage 208 is formed through the center of the conductive domain 204. Although one second permeable passage 208 is shown in FIG. 2, a plurality of second permeable passages 208 may be disposed through any of the contact elements 150, such as through an abrasive domain 202. The plurality of second permeable passages 208 may also be formed in a combination of abrasive domains 202 and conductive domains 204.

The sub-pad 211 may be a compressible material that may be softer and more compressible than the upper portion 212. Examples of suitable sub-pads, materials, thicknesses, and compressibility or hardness parameters are disclosed in U.S. Patent Application No. 60/516,680, filed Nov. 3, 2003, entitled “Composite Polishing Pad Assembly for Electrochemical Mechanical Polishing (ECMP)”, previously incorporated by reference.

In the embodiment depicted in FIG. 2, the upper and lower interpose layers 207, 209 are on opposing sides of the sub pad 211 and are adapted to provide enhanced mechanical strength and promote adhesion to the adjacent layers. For instance, the upper interpose layer 207 provides improved mechanical strength to the upper portion 212 and the lower interpose layer 209 provides mechanical strength to the sub pad 211. In certain embodiments, the upper portion 212, comprising a plurality of contact elements 150 disposed on a conductive carrier 206, lacks sufficient mechanical integrity or strength to endure prolonged planarization or polishing processes. Additionally, the sub pad 211 may be made of a material chosen for its porosity, but that material may lack sufficient mechanical strength. The upper and lower interpose layers 207, 209 are made of a material, such as a suitable plastic material including, but not limited to polymers, ligomers, co-polymers, for example, Mylar® PET polymers available from Dupont. The material will be chosen to provide extra mechanical strength to these layers, thereby enhancing polishing performance and extending service life of the pad body 122. The interpose layers 207, 209 may also be roughened in order to increase adhesion of a suitable binder.

Without being limited to any particular theory, the configuration of the pad body 122 permits the downward force from the carrier head 104 to flatten the upper portion 212 at low pressures, even at pressures of 0.5 psi or less, for example, 0.3 psi or less, such as 0.1 psi, and thus substantially compensate for small variations in the surface topography of the upper portion 212. For example, the variations in topography of the upper portion 212 may be absorbed by the compressive qualities of the sub-pad 211, so that the processing surface 125 remains in substantially uniform contact with the substrate 114 across the feature surface 115. As a result of the material properties, a uniform pressure can be applied to the substrate 114 by the processing pad, thereby improving processing uniformity during low pressure processing. Consequently, materials that require low-pressure processing to avoid delamination, such as low-k dielectric materials, can be processed with an acceptable degree of uniformity. It is contemplated that the embodiments of the sub-pad 211 disclosed above are applicable to any embodiment of processing pad assemblies disclosed herein that have sub-pads.

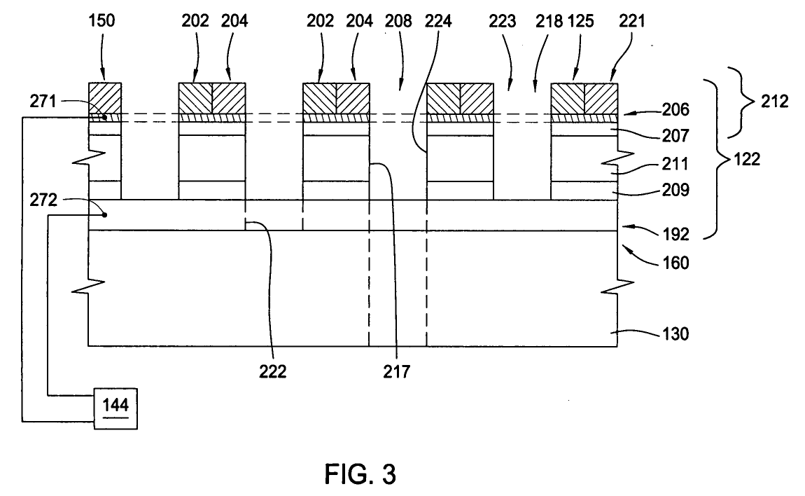

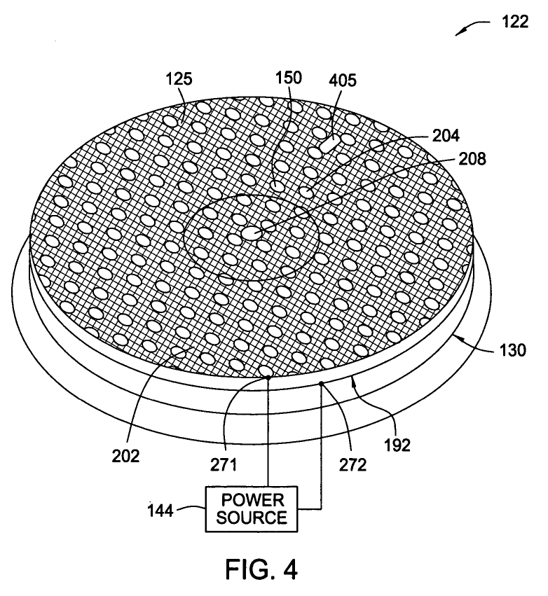

The electrode 192 is coupled to the power source 144 and may act as a single electrode, or may comprise multiple independently biasable electrode zones isolated from each other. Embodiments of various zoned electrodes can be found in the description of FIGS. 3 and 4 in U.S. Patent Application No. 60/516,680, filed Nov. 3, 2003, entitled “Composite Polishing Pad Assembly for Electrochemical Mechanical Polishing (ECMP)”, previously incorporated by reference in its entirety.

The electrode 192 is typically comprised of a corrosion resistant conductive material, such as metals, conductive alloys, metal coated fabrics, conductive polymers, conductive pads, and the like. Conductive metals include tin, nickel, copper, gold, and the like. When metal is used as the material for the electrode 192, it may be a solid sheet. Alternatively, the electrode 192 may be perforated or formed of a metal screen in order to increase the adhesion to the lower interpose layer 209 or the optional sub-pad 211. The electrode 192 may also be primed with an adhesion promoter to increase the adhesion to the lower interpose layer 209. An electrode 192 which is perforated or formed of a metal screen also has a greater surface area which further increases the substrate removal rate during processing.

The contact elements 150 disposed on the conductive carrier 206 are electrically separated from electrode 192. In the embodiment depicted in FIG. 2, the conductive carrier 206 is disposed on a dielectric upper interpose layer 207, a dielectric sub-pad 211 and a dielectric lower interpose layer 209 disposed on the electrode 192. Although all of the layers between the conductive carrier 206 and the electrode 192 have been shown to be insulative or dielectric, it is contemplated that only one of the layers need have insulative properties to electrically separate the carrier 206 from the electrode 192.

The conductive carrier 206 is typically comprised of a corrosion resistant conductive material, such as metals, conductive alloys, metal coated fabrics, conductive polymers, conductive pads, and the like. Conductive metals include tin, nickel, copper, gold, and the like. Conductive metals also include a corrosion resistant metal such as tin, nickel, or gold coated over an active metal such as copper, zinc, aluminum, and the like. Conductive alloys include inorganic alloys and metal alloys such as bronze, brass, stainless steel, or palladium-tin alloys, among others. Metal coated fabric may be woven or non-woven with any corrosion resistant metal coating. The conductive carrier 206 material should be chosen for compatibility with electrolyte chemistries. The conductive metals and conductive alloys listed above may maximize compatibility of the conductive carrier 206 to the electrolyte chemistry.

In the embodiment depicted in FIG. 2, it is contemplated that the conductive composite material 221 will form the conductive domains 204 of the contact elements 150. The conductive composite material 221 may comprise conductive materials disposed in a polymer binder, described above in detail in reference to contact element 150, is formed over the conductive carrier 206. The conductive carrier 206 is in electrical communication with the conductive composite material 221 and the conductive domain 204 disposed thereon. The conductive carrier 206 is coupled to the power source 144 by an electrical connection, such as a first terminal 271 which is adapted to translate an electrical signal to the processing surface 125 that in one embodiment is substantially planar. The conductive processing surface 125 may alternatively be perforated or textured. The electrode 192 is connected to an opposing pole of the power source 144 by an electrical connection, such as a second terminal 272.

The abrasive domains 202 may be fabricated from polymeric materials compatible with process chemistry, examples of which include polyurethane, polycarbonate, nylon, acrylic polymers, epoxy, fluoropolymers, PTFE, PTFA, polyphenylene sulfide (PPS), or combinations thereof, and other polishing materials used in polishing substrate surfaces. In one embodiment, the abrasive domains 202 of the pad body 122 are dielectric. For example, a plurality of abrasive domains 202 may be formed from by compressing a non conductive plastic patterning mask screen, such as polyurethane or other polymer that exhibits high abrasive qualities, having a suitable plurality of holes or dies to form the contact elements 150, onto the conductive composite 221. The holes or dies may be a variety of shapes and designs, such as ovals, frustums, substantial rectangles, or polygons. Designs of the plurality of contact elements 150 will be discussed further below. The plastic patterning mask is then left in the conductive composite 221 to form the abrasive domains 202 of the contact elements 150. It is also contemplated that the plastic patterning mask may be made of conductive materials that will add to the conductive area disposed on the processing surface 125 while concurrently exhibiting efficient abrasive characteristics.

The first permeable passage 218 in the upper portion 212 can be manufactured, e.g., by the previously described molding process, with the permeable passage 218 formed in the upper portion 212 during molding of the conductive composite 221. In one molding process, e.g., injection molding or compression molding, the pad material cures or sets in a mold that has indentations that form the first permeable passage 218. Alternatively, the upper portion 212 can be manufactured by a more conventional technique, e.g., by skiving a thin sheet of pad material from a cast block. The first permeable passages 218 may be part of a porous conductive pad material or the permeable passages 218 may be formed by machining the upper portion 212. A plurality of first permeable passages 218 may also comprise channels 223 in the processing surface 125.

FIG. 3 depicts another embodiment of the pad body 122. The pad body 122 comprises a first conductive layer, such as an upper portion 212, a first interpose layer, such as an upper interpose layer 207, a sub-pad 211, a second interpose layer, such as a lower interpose layer 209, and a second conductive layer, such as an electrode 192. The upper portion 212 of the pad body 122 comprises a processing surface 125 disposed on a conductive carrier 206. The processing surface 125 comprises a plurality of contact elements 150, which comprise a plurality of conductive surfaces, such as conductive domains 204 and a plurality of non conductive surfaces, such as abrasive domains 202. In this embodiment, multiple contact elements 150 are a combination of conductive domains 204 and abrasive domains 202 disposed adjacent each other and separated by grooves, such as channels 223. Also shown is a plurality of first permeable passages 218 formed by any method previously discussed or any process known in the art. As in FIG. 2, the passages 218 may extend through the conductive carrier 106, the sub-pad 211, and the interpose layers 207, 209 to the electrode 192. The passages may optionally extend through the electrode 192 as shown by optional extension 222. Also shown is an optional second permeable passage 208, which may extend through the electrode 192 and the top surface 160 of the platen assembly 130. The conductive carrier 206 is connected to one pole of the power supply 144 and the electrode 192 is connected to an opposing pole by suitable electrical connections, such as first and second terminals 271 and 272.

In the embodiment depicted in FIG. 3, the upper portion 212 may be formed by compression molding or embossing a conductive composite 221 with a first patterned screen that is chosen for qualities such as abrasion and leaving the screen to form the abrasive domains 202. The shapes and patterns of the first screen may displace the conductive composite 221 at least to the conductive carrier 206, thereby forming conductive areas and abrasive areas on the processing surface 125. The upper portion 212 may then be compression molded again with a second patterned screen with a suitable number and pattern of dies, to remove a portion of the abrasive areas formed from the first patterned screen, and a portion of the displaced i.e., remaining conductive composite 221 to form the abrasive domains 202 and the conductive domains 204, respectively. The resulting upper portion 212 may then be finished to exhibit a surface roughness of about 500 microns or less.

In an alternative embodiment, the upper portion 212 may be formed by compression molding a first patterned screen onto the conductive composite 221 and then removing the patterned screen, forming abrasive areas with a plurality of perforations therebetween, after removal of the screen. The plurality of perforations may then be filled, such as by applying a coating of an abrasive polymer to the upper portion 212 forming a substantially planar surface of conductive areas and abrasive areas in the filled perforations. The substantially planar surface is then perforated again with a second patterned screen with a suitable number and pattern of dies, to remove a portion of the abrasive areas and a portion of the conductive areas of the upper surface to form the abrasive domains 202 and the conductive domains 204, respectively. The resulting upper portion 212 may then be finished to exhibit a surface roughness of about 500 microns or less.

FIG. 4 depicts a pad body 122 that is an isometric view of the pad body 122 of FIG. 2, including a processing surface 125 having annular shaped contact elements 150, such as a plurality of conductive domains 204 dispersed in a plurality of abrasive domains 202. Also shown is a second permeable passage 208 and an aperture, such as a window 405 in the pad body 122 that allows access for an optical device such as, a laser. One pole of the power source 144 will be connected to the conductive carrier 206 by a terminal 271 which will be in electrical communication with the conductive domains 204 in the processing surface 125. Alternatively or additionally, the power source 144 may be in electrical communication with the abrasive domains 202 and the conductive domains 204 when the abrasive domains 202 are formed from a conductive material that exhibits abrasive qualities. The opposing pole of the power source 144 will be connected by a terminal 272 to the electrode 192 to create an electrical potential in the pad body 122.

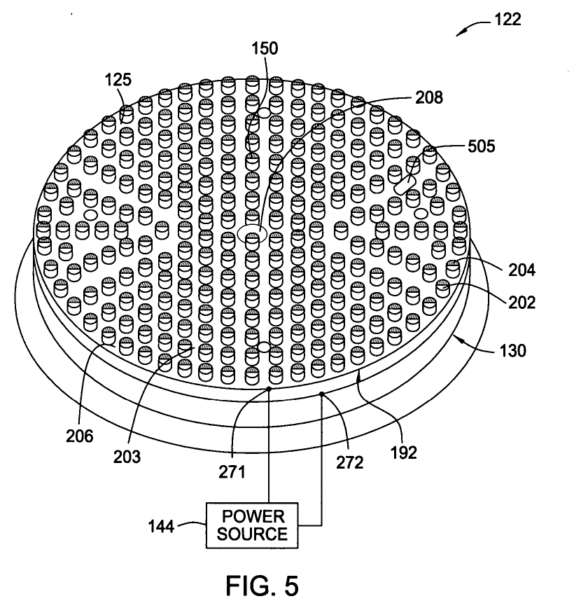

FIG. 5 is an isometric view of the pad body 122 depicted in FIG. 3 having a plurality of contact elements 150 that are substantially annular. The contact elements 150 have a portion that is an abrasive domain 202 disposed adjacent a portion that is a conductive domain 204. A channel 203 is also shown that is bounded on a lower side by the conductive carrier 206. One pole of the power source 144 will be connected to the conductive carrier 206 by a terminal 271 which will be in electrical communication with the conductive domains 204 in the processing surface 125. Alternatively or additionally, the power source 144 may be in electrical communication with the abrasive domains 202 and the conductive domains 204 when the abrasive domains 202 are formed from a conductive material that exhibits abrasive qualities. The opposing pole of the power source 144 will be connected by a terminal 272 to the electrode 192 to create an electrical potential in the pad body 122. Also shown is a window 505 for an optical device.

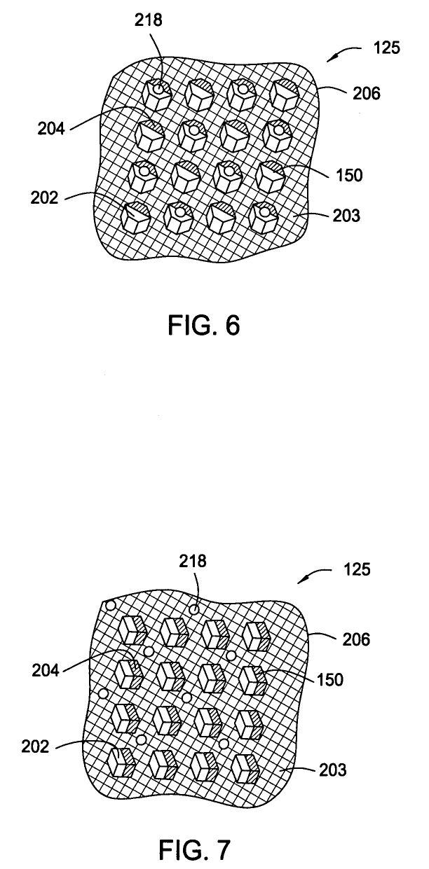

FIGS. 6 and 7 are other embodiments of the pad body 122 of FIG. 5 depicting various shapes of the contact elements 150. FIG. 6 shows a substantially hexagonal shaped contact element 150, a portion of which may be a conductive domain 204 adjacent a portion that is an abrasive domain 202. FIG. 7 depicts contact elements 150 that are substantially rectangular, a portion of which may be a conductive domain 204 adjacent a portion that is an abrasive domain 202. A channel 203 is shown in both Figures bounded on a lower surface by a conductive carrier 206.

While the foregoing is directed to embodiments of the present invention, other and further embodiments of the invention may be devised without departing from the basic scope thereof, and the scope thereof is determined by the claims that follow.

1. A pad assembly for processing a substrate, comprising:
a body comprising a conductive layer having a processing surface, and a sub-pad disposed on the conductive layer with at least one interpose layer therebetween; and
a plurality of contact elements comprising a plurality of conductive domains and a plurality of abrasive domains coupled to a conductive carrier and adapted to contact a substrate.

2. The assembly of claim 1, wherein the conductive domains comprise a conductive material disposed in a binder.

3. The assembly of claim 1, wherein the conductive domains further comprise a metal or metal alloy disposed in a binder.

4. The assembly of claim 1, wherein the conductive domains further comprise copper particles disposed in a polymer matrix.

5. The assembly of claim 1, the conductive domains further comprise nickel particles disposed in a polymer matrix.

6. The assembly of claim 1, wherein the conductive domains further comprise tin particles disposed in a polymer matrix.

7. The assembly of claim 1, further comprising a first set of holes formed through the body and exposing the conductive layer to the conductive carrier.

8. The assembly of claim 1, wherein the conductive layer and the conductive carrier are connected to opposing poles of a power supply.

9. A pad assembly for processing a substrate, comprising:
a body with an upper conductive layer having an upper portion and a lower surface;
a first interpose layer having a lower surface and an upper surface adhered to the lower surface of the upper conductive layer;
a sub pad having a lower surface and an upper surface adhered to the lower surface of the first interpose layer;
a second interpose layer having a lower surface and an upper surface adhered to the lower surface of the sub pad; and
an opposing second conductive layer having a lower surface and an upper surface adhered to the lower surface of the second interpose layer.

10. The assembly of claim 9, wherein the upper portion defines a processing surface and further comprises a plurality of contact elements.

11. The assembly of claim 9, wherein the processing surface further comprises a conductive composite and a dielectric polymer.

12. The assembly of claim 11, wherein the processing surface comprises a plurality of conductive domains and a plurality of abrasive domains.

13. The assembly of claim 9, wherein the upper conductive surface and the second conductive surface are connected to opposing poles of a power supply.

14. The assembly of claim 12, wherein the conductive composite further comprises a conductive material disposed in a binder.

15. The assembly of claim 12, wherein the conductive composite further comprises a metal or metal alloy disposed in a binder.

16. The assembly of claim 12, wherein the conductive composite further comprises copper particles disposed in a polymer matrix.

17. The assembly of claim 12, the conductive composite further comprises nickel particles disposed in a polymer matrix.

18. The assembly of claim 12, wherein the conductive composite further comprises tin particles disposed in a polymer matrix.

19. The assembly of claim 9, further comprising a set of holes formed through the body and exposing the first conductive layer to the second conductive layer.

20. A conductive pad assembly for processing a substrate, comprising:
a body with a first conductive layer and an opposing conductive layer with a dielectric layer therebetween; and
a plurality of contact elements disposed on the body, a portion of each of the contact elements adapted to communicate an electrical bias to a substrate while abrading the substrate.
